(19) United States
(12) Patent Application Publication
(10) Pub. No.: US 2025/0385204 A1
(43) Pub. Date: Dec. 18, 2025

(54) STRUCTURES AND MATERIALS FOR REDUCING IN-PLANE STRESSES AND VOIDS - CREATING AN OPTIMIZED HYBRID BONDING INTERFACE

(71) Applicant: INTERNATIONAL BUSINESS MACHINES CORPORATION, ARMONK, NY (US)

(72) Inventors: Kishan Jayanand, COHOES, NY (US); Nicholas Alexander POLOMOFF, Hopewell Junction, NY (US); Mukta Ghate Farooq, HOPEWELL JCT, NY (US); Sathyanarayanan Raghavan, Ballston Lake, NY (US)

(21) Appl. No.: 18/744,576

(22) Filed: Jun. 14, 2024

(51) Int. Cl. H01L 23/00

(52) U.S. Cl. CPC H01L 24/05; H01L 24/03; H01L 24/08; H01L 2224/039; H01L 2224/05609; H01L 2224/05611; H01L 2224/05623; H01L 2224/05624; H01L 2224/05647; H01L 2224/05666; H01L 2224/05671; H01L 2224/05681; H01L 2224/05684; H01L 2224/0812

(57) ABSTRACT

A hybrid bonded interface structure includes a primary conduction path constructed of a first material layer. A second material layer for stress-absorption and void reduction is arranged along a perimeter of the first material layer. A crack stop and diffusion barrier formed of a third material layer is arranged along a perimeter of the second material. A Young's modulus of the third material layer is greater than a Young's modulus of the second material layer and a Young's Modulus of the first material layer.

### BACKGROUND

### Technical Field

The present disclosure generally relates to structures and methods for joining components such as dies and wafers, and more particularly, to hybrid bonding including a dielectric and metal pads.

### Description of the Related Art

Hybrid bonding is a permanent bonding process that combines a dielectric bond (e.g., SiOx) with an embedded metal (e.g., Cu pads) to form interconnections. Hybrid bonding is becoming increasingly popular due to the miniaturization of components that increase the difficulty of using bump bonds.

### SUMMARY

In one embodiment, a hybrid bonded interface structure includes a primary conduction path constructed of a first material layer. A second material layer for stress-absorption and void reduction is arranged along a perimeter of the first material layer. A crack stop and diffusion barrier formed of a third material layer is arranged along a perimeter of the second material layer, A Young's modulus of the third material layer is greater than a Young's modulus of the second material layer and a Young's Modulus of the first material layer.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates void formations in hybrid bonding contributed to stress.

FIG. 2 shows a prepackaged device undergoing mechanical chip package interaction (CPI) forces.

FIG. 3A shows a first-level and a second-level package interaction of stresses.

FIG. 3B shows stresses from thermal cycling on a prepackaged device.

FIG. 4 shows a hybrid bond using three metals with different properties, consistent with an illustrative embodiment.

FIG. 5A shows a front view of a hybrid bonding structure, consistent with an illustrative embodiment.

FIG. 5B shows a plan view of the hybrid bonding structure of FIG. 5A, consistent with an illustrative embodiment.

FIG. 5C shows a prepackaged device that includes a hybrid bonded structure consistent with an illustrative embodiment.

FIG. 6A illustrates how the use of a diffusion barrier in the hybrid bonding arrests Cu migration into the dielectric, consistent with an illustrative embodiment.

FIG. 6B is an example table that shows some of the materials that may be used for a hybrid bonded structure, consistent with an illustrative embodiment

FIG. 6C is an example table that lists some ground rules for material selection, consistent with an illustrative embodiment.

FIGS. 7A to 7C illustrate a process flow to create hybrid bonds, consistent with an illustrative embodiment.

### DETAILED DESCRIPTION

### Overview

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings.

As used herein, the term “hybrid bonding” is a type of bond that combines a dielectric bond (e.g., SiOx) with embedded metal (e.g., Cu) to form interconnections. Hybrid bonding is also known as a direct bond interconnect (DBI). According to embodiments of the present disclosure, the addition of layers with different properties than the embedded metal provides for stress-absorption and a diffusion barrier that results in a superior hybrid bond.

### Support

In an embodiment, a hybrid bonded interface structure includes a primary conduction path constructed of a first material layer. A second material layer is configured to absorb stress and void reduction, arranged along a perimeter of the first material layer. A crack stop and diffusion barrier made of a third material layer is arranged along a perimeter of the second material layer. A Young's modulus of the third material layer is greater than a Young's modulus of the second material layer and a Young's Modulus of the first material layer.

In an embodiment, the primary conduction path is constructed of Cu pads, the second material layer is Al; and the third material layer is Cr.

In an embodiment, the hybrid bonded interface structure at room temperature has an electrical conductivity in which the first material layer>the second material layer>the third material layer.

In an embodiment, the hybrid bonded interface structure is a die-to-wafer or a wafer-to-wafer connection of Cu pads forming the first material layer. dielectric material.

In an embodiment, a method of manufacturing a hybrid bonded structure, the method includes depositing a crack stop and diffusion barrier material along an etched opening of an Si layer on a dielectric material. A stress-absorbing material is deposited on the crack stop and diffusion barrier. A conductive material forming a primary conduction path is arranged on the stress-absorbing material. A Young's modulus of the crack stop and diffusion barrier is greater than a Young's modulus of the stress-absorbing material and a Young's Modulus of the conductive material forming the primary conduction path.

In an embodiment, the method further includes attaching the hybrid bonded interface to another hybrid bonded interface via the first material layer to form a die-to-wafer or wafer-to-wafer connection, wherein each die or wafer includes a Cu pad as the first material layer.

During conventional hybrid bonding at a joining interface, (e.g., including but not limited to a metal-dielectric interface), minute defects can result in catastrophic failures due to external forces acting on a device, as well as the that from annealing during the bonding process. Such hybrid bonding defects mainly occur at the interface with the metal.

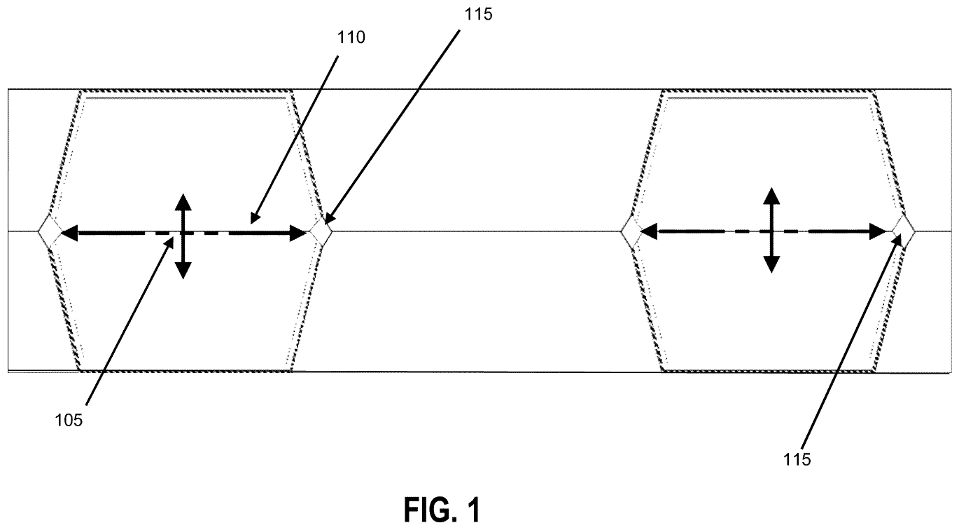

FIG. 1 shows a typical hybrid bonded structure with defects. Stress build-up along the joining interface 105 due to Cu expansion during the bonding process. The stress distribution 110 results in a shear force at the joining interface 105. These shear forces may result in “white bump failure” (e.g., low-k dielectric damage), which leads to dielectric layer delamination and cracks at the metal-dielectric interface. Void formation 115 may occur at the metal-dielectric interface, particularly seen at the edges of the joining interface 105. Chip package interaction (CPI), which is the interaction between semiconductor package stresses and semiconductor devices, may cause a device failure when the CPI is excessive due to mechanical and/or thermal stresses.

During the bonding process, copper melts and re-flows to make the interface between the bonded components. Sometimes the bonding process causes cracks in the bonding surface, and Cu migration into the dielectric upon which the Cu is embedded.

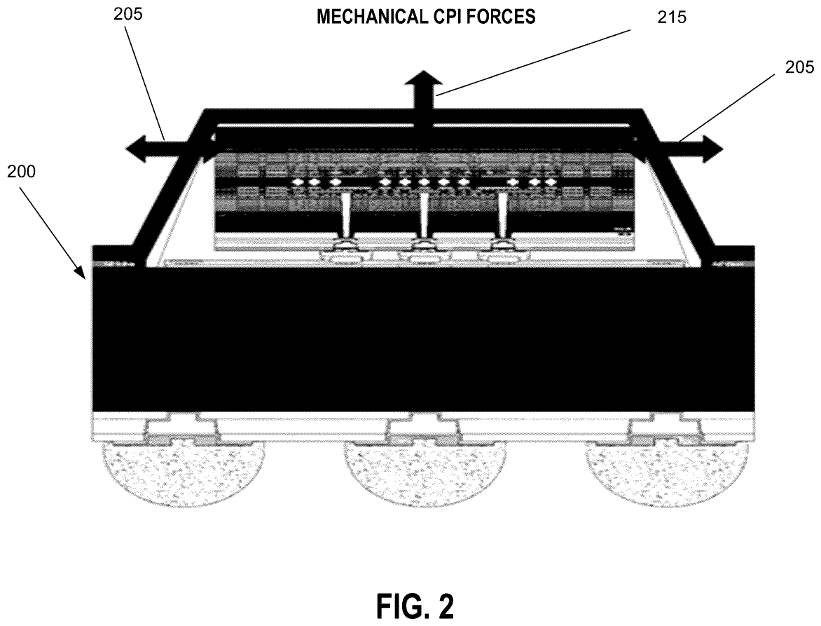

FIG. 2 shows the various mechanical CPI forces on a prepackaged device 200. There are both shear forces 205 and other mechanical forces 215 (such as from thermal expansion) that cause prepackaged device failures. The hybrid bonding inherently has defects/cracks/issues at the joining of pads, and the process of joining the pads (e.g., such as by annealing) can add to or bring additional forces and stresses.

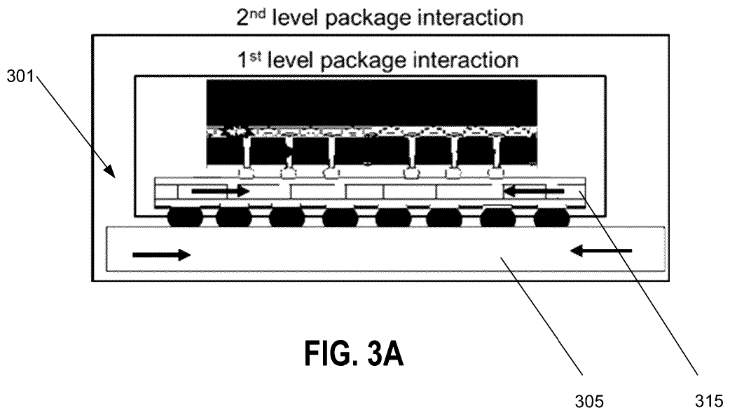

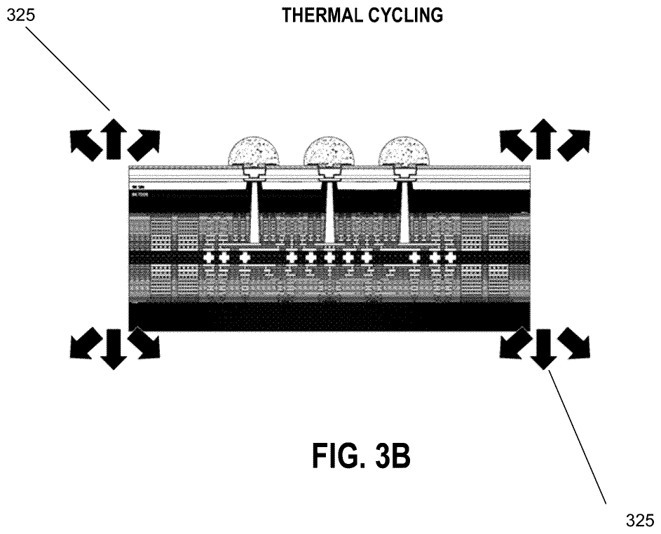

FIG. 3A shows different levels of package interaction, both by the substrates 305 and 315. The arrows indicate shear forces that contribute to cracks that cause device failures.

FIG. 3B shows the various stresses 325 on the prepackaged device 301 from thermal cycling. The device may have both shear forces and thermal cycling stresses acting to exacerbate defects.

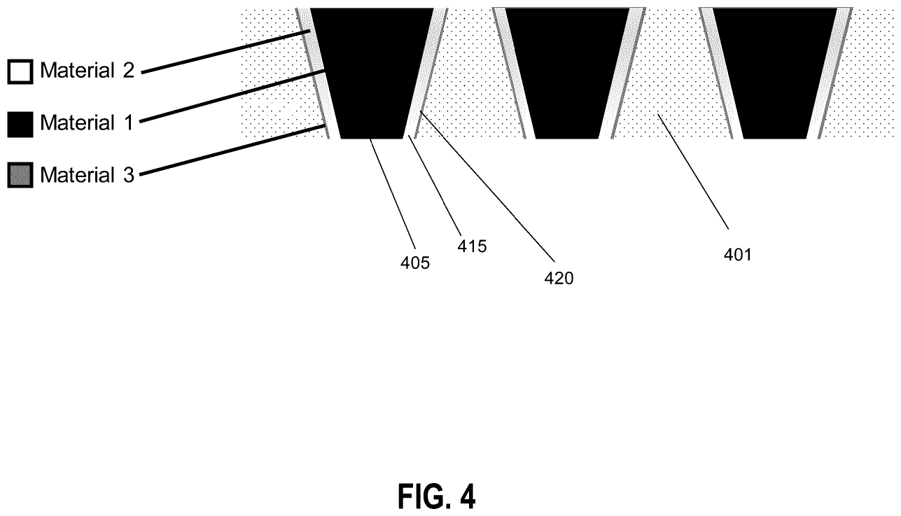

FIG. 4 shows a hybrid bond using three metals with different properties, consistent with an illustrative embodiment. FIG. 4 shows a structure with a dielectric material 401 in which copper 405 is embedded as a first material. However, in addition to the copper, a second material 415 for stress-absorption is provided around a perimeter of the copper. A third material 420, having increased hardness compared to the first material and the second material, is added around the perimeter of the second material 415 to form a crack stop and create a barrier diffusion. Thus, the hybrid structure according to an embodiment of the present disclosure has reduced defects and there is a reduction or near elimination of mitigation of the first material 405 from diffusing into the dielectric and adversely impacting the operation of the device. In an embodiment, the hybrid bonded interface structure at room temperature has an electrical conductivity in which a layer of the first material 405>a layer of the second material 415>a layer of the third material 420. For example, the electrical conductivity of Cu>Al>Cr. Approximate electrical conductivity ratios of Cu:Al:Cr=15:10:2.

In an embodiment, the second material 415 is Aluminum (Al) is sandwiched between copper (Cu) (first material 405) and Chromium (Cr) as the third material 420 to act as a cushion. The Cu provides a primary conduction production path. The Al and the Cr have a lower conductivity than Cu. The Al second material 415 absorbs stress to reduce cracks in the Cu, and the Cr acts as a crack stop for cracks that may form in the Cu, and to serve as a diffusion barrier to prevent Cu from migrating into the dielectric 401. The Cr absorbs most of the energy being propagated which causes cracks to expand.

### Example Embodiment

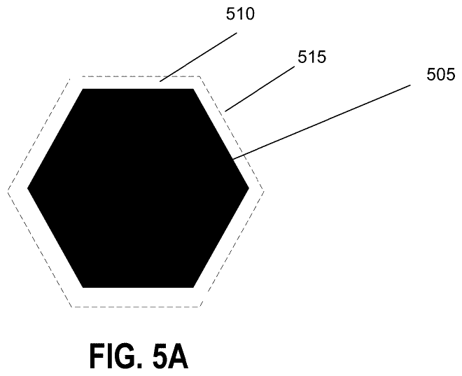

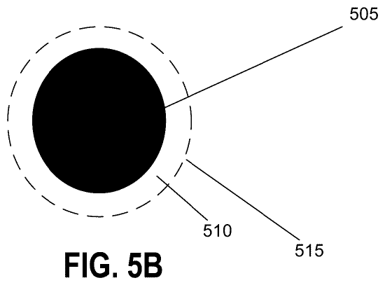

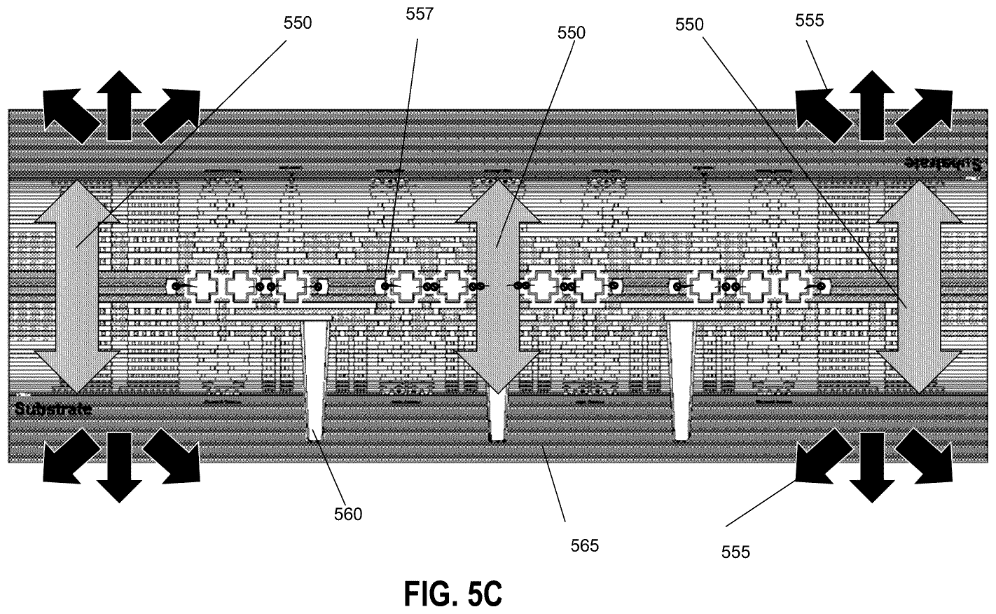

FIG. 5A shows a front view of a hybrid bonding structure, consistent with an illustrative embodiment. FIG. 5B shows a plan view of the structure of FIG. 5A. A Cu layer 505, has a stress-absorbing cushion 510 and a crack stop and diffusion layer 515. It should be noted that although the three layers have different electrical conductivity at room temperature, the electrical conductivity of Cu is significantly greater than Al and Cr, resulting in most of the signal choosing Cu as the path of least resistance. The use of Al and Cr as a result does not introduce noise, as most of the signals flow through the Cu.

It is to be understood that the hybrid bonded structure is not limited to the use of Al and Cr, and there are other substances that may be used as discussed herein below as examples. In addition, it is within the scope of the disclosure that a polymer may be used as a cushioning force.

FIG. 5C shows a prepackaged device that includes a hybrid bonded structure consistent with an illustrative embodiment. There are identified thermal stresses 550, along with mechanical stresses 555. Through Silicon Vias (TSV) 560, which may be constructed with a material such as copper, and Al and Cr layers as discussed above, are shown extending into the substrate 565. The circles 557 represent the formation of voids in the low k dielectric surrounding the Cu pads at hybrid bonding interface.

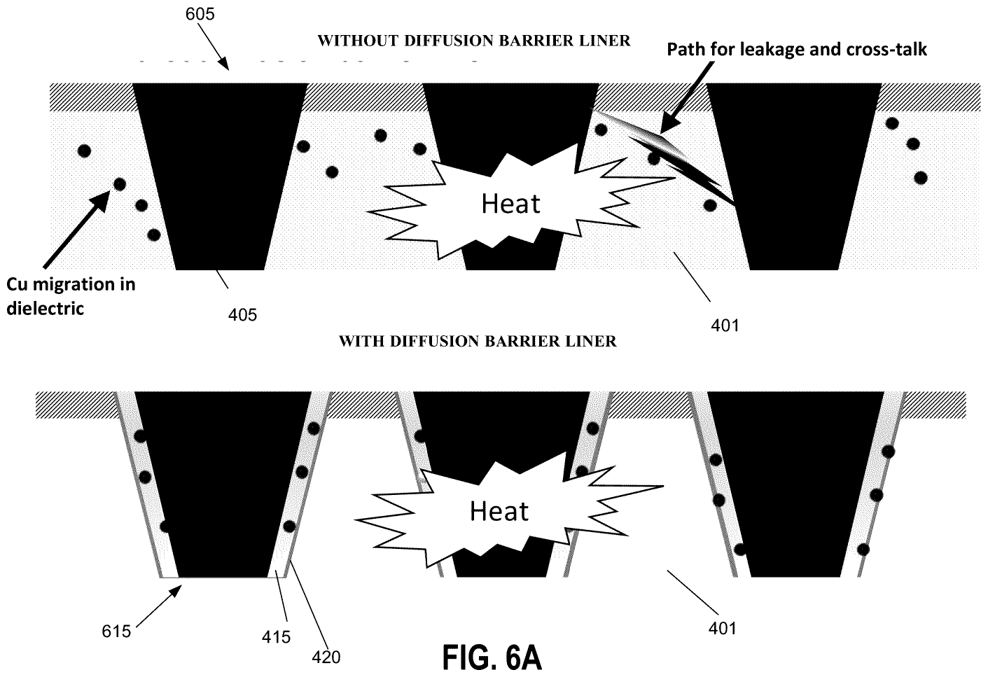

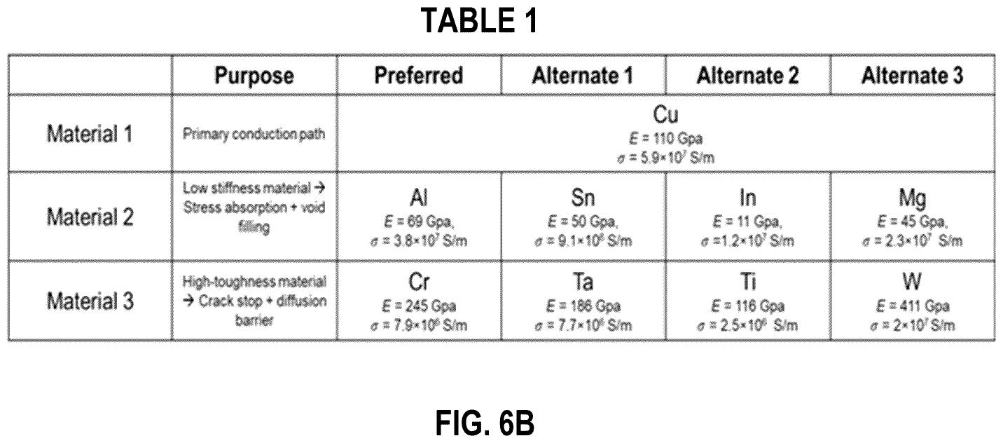

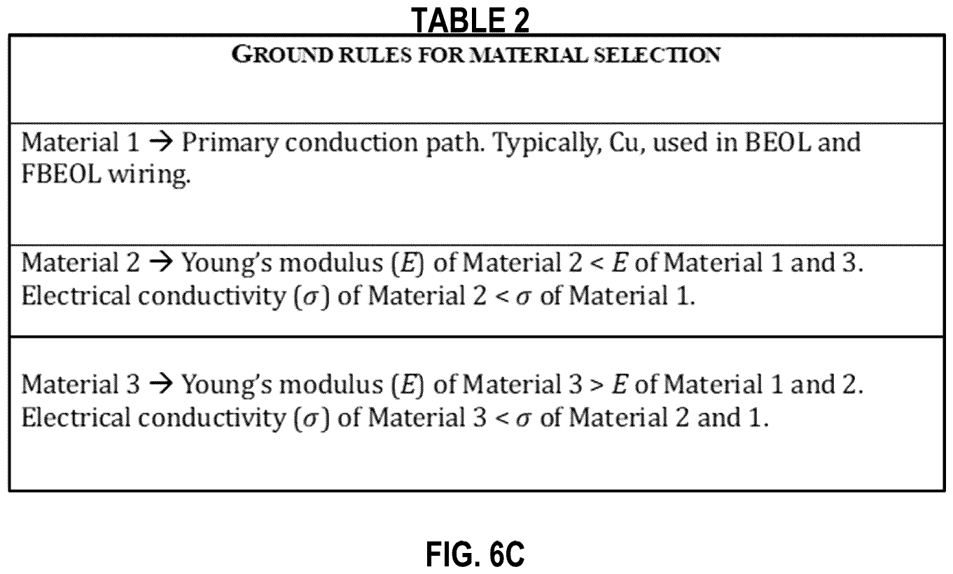

FIG. 6A illustrates how the use of a diffusion barrier in the hybrid bonding arrests Co migration into the dielectric, consistent with an illustrative embodiment. The first structure 605, which does not have a diffusion barrier liner, has Cu migrating from the pads (the first material 405) into the dielectric 401 when (such as from annealing, or due to thermal stresses during operation of devices with hybrid bonding interfaces) is applied to the first structure 605. However. the second structure 615 according to an embodiment of the present disclosure has the second material 415 for stress-absorption and a third material 420 that serves as a crack strop and diffusion barrier. It can be seen that due to thermal stresses during normal operation of devices, or from the application of heat, such as when annealing is performed, the copper from the first material 405 is blocked from migrating into the dielectric 401 by the crack stop and diffusion barrier, which may be constructed of Cr. The migration of Cu into the dielectric 401 can degrade performance and ultimately result in catastrophic device failures

FIG. 6B shows a table (i.e., Table 1) shows some of the materials that may be used for a hybrid bonded structure, consistent with an illustrative embodiment. Although the first material 405 is Cu, it is to be understood that other conductors could be used. However, as Cu is the typical material for pads for the primary conduction path, alternatives were not provided.

The second material 415 should be a material with low stiffness for stress absorption and void filling. While Al is the preferred material, Sn, In and Mg are examples of substitute materials. It is to be understood that the appended claims are not limited to the example materials, that have been provided for illustrative purposes.

The third material 420 is preferably Cr. However, materials with a high toughness that can serve as a crack stop and diffusion barrier for the first material 405 may be substituted. For example, Ta, Ti, and W are all materials that may be used for a crackstop and diffusion barrier. It is also understood that any of the materials listed in Table 1 as material 2 can be used in conjunction with any of the materials listed as material 3.

FIG. 6C (i.e., Table 2) lists some ground rules for material selection, consistent with an illustrative embodiment. Material 1 is typically Cu, as this is an industry stand used in BEOL and FBEOL wiring. The second material should have a Young's Modulus less than the Cu material and the third material, Al is often a candidate for selection. Also, the conductivity of the second material should be less than the first material. The third material should have a hardness to function as a crack stop and diffusion barrier, and thus a Young's Modulus of the third material should be greater than the first material and the second material. Cr is a very good candidate for selection, but as shown above in Table 1, substitute materials may be used. The electrical conductivity of the third material should be less than the first material and the second material so that the primary signal flow is through the path of the first material.

### Example Process

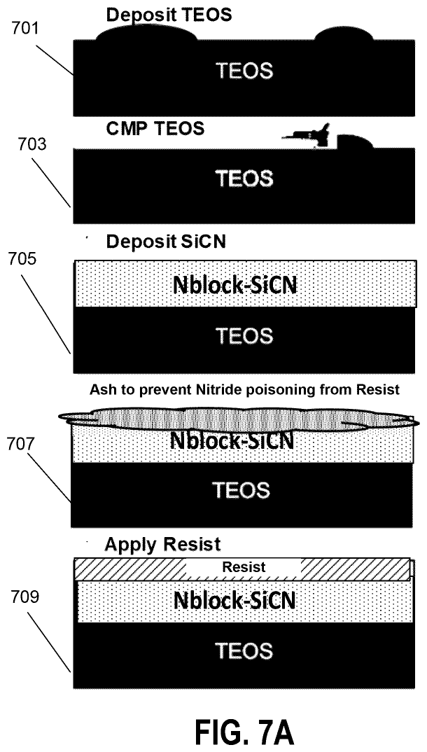

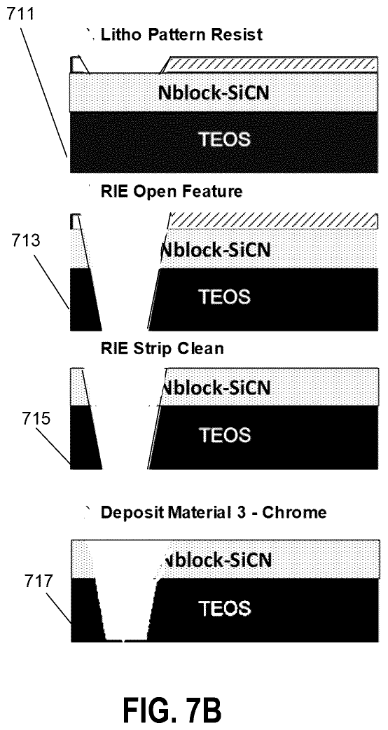

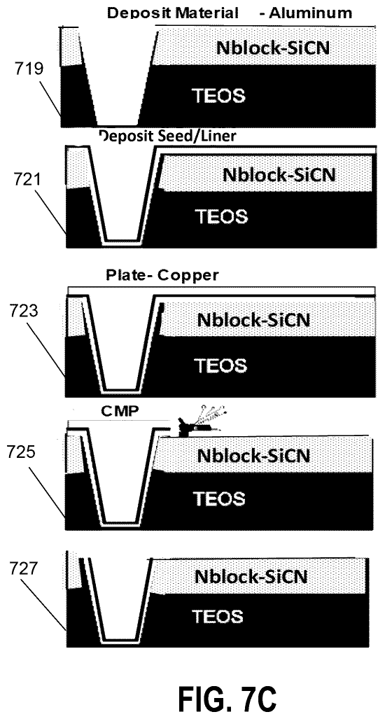

With the foregoing overview of the example architecture, it may be helpful now to consider a high-level discussion of an example process. To that end, FIGS. 7A to 7C provide a process flow of the hybrid bonded structure according to an embodiment of the present disclosure. FIGS. 7A to 7C are shown in a logical order, which represents a sequence of operations. In this process, the order in which the operations are described is not intended to be construed as a limitation, and any number of the described blocks can be combined in any order and/or performed in parallel to implement the process.

A dielectric such as tetraethyl orthosilicate (TEOS) is deposited on a workpiece (operation 701). Chemical mechanical polishing (CMP) is performed (operation 703). SiCN is deposited on the TEOS (operation 705) and then ash is deposited on the SiCN (e.g., using an ashing process in which a low power O₂ plasma oxidizes the surface of SiCN) to prevent resist poisoning (i.e., contamination) from a resist layer (707).

In FIG. 7B, a resist layer is applied (operation 709), followed by a lithographic pattern resist (operation 711). Reactive Ion Etching (RIE) is performed to construct an opening in the SiCN and the TEOS, and the resist layer is removed (operation 715). A material with a high hardness such as Cr is deposited to install the crack-stop barrier (operation 717).

Referring now to FIG. 7C, a stress-absorbing material such as Al is deposited on the Cr (operation 719), and then a seed/liner is deposited on the aluminum. (operation 721). Cu is then deposited to fill in the etched gap as the primary conductor (operation 723) and CMP is performed on the Cu (operation 725). After the CMP is performed, the structure has an interface that is ready to be bonded by hybrid bonding, for example, to copper pads of another structure, and heating by annealing (operation 727). It is to be understood that the order in which the primary conductor, stress-absorbing material and crack-stop diffusion barrier material are applied may be different.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

The flowchart, and diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best of optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A hybrid bonded interface structure, comprising:
a primary conduction path constructed of a first material layer;
a second material layer configured to absorb stress and void reduction, arranged along a perimeter of the first material layer; and
a crack stop and diffusion barrier comprising a third material layer arranged along a perimeter of the second material layer,
wherein a Young's modulus of the third material layer is greater than a Young's modulus of the second material layer and a Young's Modulus of the first material layer.

2. The hybrid bonded interface structure according to claim 1, wherein:
an electrical conductivity of the third material layer is less than an electrical conductivity of the second material layer; and
the electrical conductivity of the second material layer is less than an electrical conductivity of the first material layer.

3. The hybrid bonded interface structure according to claim 2, wherein the first material layer comprises Cu.

4. The hybrid bonded interface structure according to claim 3, wherein;
the primary conduction path comprises Cu pads;
the second material layer comprises Al; and
the third material layer comprises Cr.

5. The hybrid bonded interface structure according to claim 4, wherein at room temperature an electrical conductivity of the first material layer>the second material layer>the third material layer.

6. The hybrid bonded interface structure according to claim 3, wherein:
the second material layer comprises Al; and
the third material layer is selected from a group consisting essentially of Ta, Ti and W.

7. The hybrid bonded interface structure according to claim 3, wherein:
the second material layer is a metal selected from the group consisting essentially of Sn, In, and Mg; and
the third material layer comprises Cr.

8. The hybrid bonded interface structure according to claim 3, wherein:
the second material layer is a metal selected from the group consisting essentially of Sn, In, and Mg; and
the third material layer is a metal selected from the group consisting essentially of Ta, Ti and W.

9. The hybrid bonded interface structure according to claim 3, comprising a die-to-wafer or a wafer-to-wafer connection of Cu pads forming the first material layer.

10. The hybrid bonded interface structure according to claim 9, wherein the Cu pads are embedded in a dielectric material comprising tetraethyl orthosilicate (TEOS).

11. A method of forming a hybrid bonding interface, the method comprising:
arranging on a dielectric a primary conduction path constructed of a first material layer;
arranging a second material layer for stress-absorption and void reduction along a perimeter of the first material layer; and
arranging a crack stop and diffusion barrier comprising a third material layer along a perimeter of the second material layer,
wherein a Young's modulus of the third material layer is greater than a Young's modulus of the second material layer and a Young's Modulus of the first material layer.

12. The method according to claim 11, wherein:
the third material layer is selected to have an electrical conductivity less than an electrical conductivity of the second material layer; and
the second material layer is selected to have an electrical conductivity less than an electrical conductivity of the first material layer.

13. The method according to claim 11, wherein Cu is arranged on the dielectric as the first material layer.

14. The method according to claim 13, wherein:
Al is arranged as the second material layer along the perimeter of the first material layer; and
Cr is arranged as the third material layer along the perimeter of the second material layer.

15. The method according to claim 11, further comprising:
attaching the hybrid bonded interface to another hybrid bonded interface via the first material layer to form a die-to-wafer or wafer-to-wafer connection,
wherein each die or wafer includes a Cu pad as the first material layer.

16. A method of manufacturing a hybrid bonded structure, the method comprising:
depositing a crack stop and diffusion barrier material along an etched opening of an SiCN layer on a dielectric material;
depositing a stress-absorbing material on the crack stop and diffusion barrier; and
arranging on the stress-absorbing material a conductive material forming a primary conduction path,
wherein a Young's modulus of the crack stop and diffusion barrier is greater than a Young's modulus of the stress-absorbing material and a Young's Modulus of the conductive material forming the primary conduction path.

17. The method according to claim 16, arranging the conductive material on the stress-absorbing material in a form of Cu pads.

18. The method according to claim 16, further comprising:
depositing Cr as the crack stop and the diffusion barrier; and
depositing Al as the stress-absorbing material.

19. The method according to claim 16, wherein:
the crack stop and diffusion barrier material is selected to have an electrical conductivity that is less than an electrical conductivity of the stress-absorbing material; and
the electrical conductivity of the stress-absorbing material is less than an electrical conductivity of the conductive material forming the primary conduction path.

20. The method according to claim 16, wherein:
the stress-absorbing material is selected from a metal consisting essentially of Sn, In, and Mg; and
the crack stop and diffusion barrier material is selected from a metal consisting essentially of Ta, Ti and W.
